(19) United States
(12) Patent Application Publication
(10) Pub. No.: US 2008/0048788 A1
(43) Pub. Date: Feb. 28, 2008

(54) FREQUENCY TUNING METHOD FOR VOLTAGE CONTROLLED OSCILLATOR AND PHASE LOCKED LOOP USING THE SAME

(76) Inventor: Hwa-Yeal Yu, Bucheon-si (KR)

Correspondence Address: F. CHAU & ASSOCIATES, LLC, 130 WOODBURY ROAD, WOODBURY, NY, 11797, US

(21) Appl. No.: 11/610,012

(22) Filed: Dec. 13, 2006

(30) Foreign Application Priority Data
Apr. 18, 2006 (KR) 10-2006-0034906

(51) Int. Cl. H03L 7/00

(52) U.S. Cl. 331/16

(57) ABSTRACT

A frequency tuning method for a voltage controlled oscillator includes outputting a first frequency selected from 2ⁿ discrete frequencies included in a frequency tuning range of the voltage controlled oscillator based on a predetermined control voltage and an n-bit control code during coarse tuning; outputting a third frequency corresponding to an average of the first frequency and a second frequency, that is, ½ of a code interval in response to the predetermined control voltage, the n-bit control code, and a control bit; and locking an output frequency of the voltage controlled oscillator to a reference frequency based on an analog control voltage and the third frequency during fine tuning. The second frequency is adjacent to the first frequency amoung the 2ⁿ discrete frequencies and the third frequency is used as an initial frequency in the fine tuning.

### BACKGROUND OF THE INVENTION

This application claims priority under 35 U.S.C. § 119 Korean Patent Application No. 10-2006-0034906, filed on Apr. 18, 2006, the disclosure of which is hereby incorporated by reference herein as if set forth in its entirety.

1. Technical Field

The present disclosure relates to frequency tuning technology for a voltage controlled oscillator (VCO), and more particularly, to a high-speed and high-accuracy frequency tuning method for a VCO and a phase locked loop (PLL) using the same.

2. Discussion of the Related Art

Generally, a L-C tank circuit including a capacitor bank is used to form a wide band VCO in frequency synthesizers requiring such a wide band. A wide band VCO including a L-C tank circuit obtains a wide band frequency by appropriately controlling the capacitance of a capacitor array included in the capacitor bank.

FIG. 1 is a basic block diagram of a conventional PLL 10 including an automatic frequency controller (AFC) 20 and a VCO 18. Referring to FIG. 1, the conventional PLL 10 includes a phase frequency detector (PFD) 12, a charge pump (CP) 14, a low pass filter (LPF) 16, the VCO 18, a switch, and the AFC 20.

During coarse tuning for the PLL 10, an initial control voltage is applied to the VCO 18 via the switch. During fine tuning, an analog control voltage Vtune is applied to the VCO 18 via the switch. A half of power supply voltage Vdd, that is, Vdd/2 is used as the initial control voltage.

The PFD 12 receives a frequency of a reference signal, referred to as a “reference frequency fref”, and a frequency of a feedback signal, referred to as a “feedback frequency fvco”, output from the VCO 18 and outputs a first or second phase control signal UP or DOWN, corresponding to a phase difference between the reference frequency fref and the feedback frequency fvco, to the CP 14. The reference frequency fref is output from a crystal oscillator (not shown) that generates a fixed stable frequency.

The CP 14 supplies a predetermined current (or charges) to the LPF 16 in response to the first phase control signal UP and discharges current (or charges) stored in a capacitor of the LPF 16 in response to the second phase control signal DOWN. The LPF 16 is implemented as a loop filter, removes high-frequency noise from the current supplied from the CP 14, and generates the analog control voltage Vtune.

During the coarse tuning, the VCO 18 outputs one frequency among 2ⁿ discrete frequencies as the feedback frequency fvco in response to an n-bit control code CODE and the initial control voltage Vdd/2. During the fine tuning, the VCO 18 outputs as the feedback frequency fvco a frequency fine tuned based on a frequency finally selected during the coarse tuning and the analog control voltage Vtune. In other words, during the fine tuning, the VCO 18 outputs as the feedback frequency fvco a frequency moving along a frequency curve finally selected during the coarse tuning based on the analog control voltage Vtune output from the LPF 16. When the reference frequency fref and the feedback frequency fvco, which are input to the PFD 12, are the same, the feedback frequency fvco is locked to the reference frequency fref.

FIG. 2 illustrates a frequency tuning procedure for the VCO 18 using conventional binary search. Referring to FIG. 2, during the coarse tuning, the AFC 20 outputs the n-bit control code CODE corresponding to a difference between the reference frequency fref and the feedback frequency fvco to the VCO 18 based on the binary search. A maximum frequency range of the VCO 18 is typically divided into 2ⁿ frequency curves.

Every time the two frequencies fref and the fvco are compared with each other, the AFC 20 determined whether the difference between the two frequencies fref and the fvco is within ½ of a code interval. It is very difficult, however, to find an exact frequency corresponding to ½ of the code interval.

The code interval indicates an interval between two adjacent frequency curves among the 2ⁿ frequency curves of the VCO 18. For example, the code interval may be an interval between a frequency curve corresponding to a 3-bit control code of “000” and a frequency curve corresponding to a 3-bit control code of “001” or an interval between a frequency curve corresponding to a 3-bit control code of “011” and a frequency curve corresponding to a 3-bit control code of “100”. A coarse tuning frequency resolution is defined as ½ of the code interval.

When the initial control voltage Vdd/2 is applied to the VCO 18 and a difference between the reference frequency fref and the feedback frequency fvco is within ½ of the code interval, as illustrated in FIG. 2, during the coarse tuning, the binary search by the AFC 20 is interrupted. For example, the VCO 18 outputs as the feedback frequency fvco a frequency f2 corresponding to the initial control voltage Vdd/2 on the frequency curve of FIG. 2 corresponding to a control code of “010”.

When a difference between the two frequencies fref and the fvco, however, is not within the frequency resolution and the reference frequency fref is higher than the feedback frequency fvco, the VCO 18 outputs as the feedback frequency fvco a frequency f3 on the frequency curve of FIG. 2 corresponding to a control code of “001”. When a difference between the two frequencies fref and the fvco is not within the frequency resolution and the reference frequency fref is lower than the feedback frequency fvco, the VCO 18 outputs as the feedback frequency fvco a frequency f4 on the frequency curve corresponding to a control code of “011”.

In other words, in the conventional AFC 20, the VCO 18 outputs as the feedback frequency fvco one frequency among three discrete frequencies f2, f3, and f4 that are adjacent one another.

FIG. 3 is a graph showing the change in a control voltage range of the VCO 18 with respect to a frequency resolution during automatic frequency control. FIG. 3 illustrates a phenomenon, in which the analog control voltage Vtune of the VCO 18 is biased to a range B or C, when the AFC 20 does not detect an exact frequency corresponding to ½ of the code interval.

Referring to FIG. 3, when the AFC 20 detects an exact frequency corresponding to ½ of a code interval, the analog control voltage Vtune of the VCO 18 has an ideal range A. However, when the AFC 20 does not detect an exact frequency corresponding to ½ of a code interval, the range of the analog control voltage Vtune of the VCO 18 may deviate from the ideal range A and be biased to the low voltage range B or the high voltage range C.

In this situation, when a variation in capacitance of the VCO 18 caused by a change of temperature is not properly compensated for, the feedback frequency fvco generated by the VCO 18 may deviate from a lock range of the VCO 18.

If the VCO 18 has the range B or C as the range of the analog control voltage Vtune (or the lock range), a large mismatch may occur in the CP 14 and, thus, increase the chances of a spurious result.

Moreover, since a code interval or a slope of a frequency curve, that is, a “VCO gain curve, may differ according to frequencies or the code interval may differ according to manufacturing processes, it is very difficult to detect an exact frequency corresponding to ½ of the code interval using the AFC 20.

In addition, since the AFC 20 determines whether a difference between the two frequencies fref and the fvco is within ½ of the code interval each time that the two frequencies fref and the fvco are compared with each other, it is difficult to detect an exact frequency corresponding to ½ of the code interval, and it takes a large amount of time to determine whether the difference between the two frequencies fref and the fvco is within ½ of the code interval, during the frequency tuning of the VCO 18 in the conventional PLL 10.

### SUMMARY OF THE INVENTION

Exemplary embodiments of the present invention provide a method and apparatus for obtaining an exact control voltage range of a voltage controlled oscillator regardless of a change in frequency or manufacturing processes, for reducing a coarse tuning time, and for detecting an exact frequency corresponding to ½ of a code interval.

According to an exemplary embodiment of the present invention, there is provided a coarse tuning method for a voltage controlled oscillator. The coarse tuning method includes outputting a first frequency on a first frequency curve finally selected from 2ⁿ frequency curves of the voltage controlled oscillator based on a predetermined control voltage and an n-bit control code, and outputting a third frequency corresponding to an average of the first frequency and a second frequency in response to the predetermined control voltage, the n-bit control code, and a control bit. The second frequency is adjacent the first frequency curve and exists on a second frequency curve among the 2ⁿ frequency curves.

According to an exemplary embodiment of the present invention, there is provided a frequency tuning method for a voltage controlled oscillator included in a phase locked loop. The frequency tuning method includes providing a predetermined control voltage to the voltage controlled oscillator during coarse tuning; outputting a first frequency finally selected from 2ⁿ discrete frequencies included in a frequency tuning range of the voltage controlled oscillator based on the predetermined control voltage and an n-bit control code; outputting a third frequency corresponding to an average of the first frequency and a second frequency in response to the predetermined control voltage, the n-bit control code, and a control bit; and locking an output frequency of the voltage controlled oscillator to a reference frequency based on an analog control voltage and the third frequency during fine tuning. The second frequency is adjacent the first frequency among the 2ⁿ discrete frequencies, and the third frequency is used as an initial frequency in the fine tuning.

According to an exemplary embodiment of the present invention, there is provided a phase locked loop including a voltage controlled oscillator and a voltage controlled oscillator control circuit. The voltage controlled oscillator control circuit generates an n-bit control code and a control bit for coarse tuning of the voltage controlled oscillator and outputs an analog control voltage for fine tuning of the voltage controlled oscillator, based on a reference frequency and an output frequency of the voltage controlled oscillator. The voltage controlled oscillator outputs a first frequency on a first frequency curve finally selected from 2ⁿ frequency curves of the voltage controlled oscillator based on a predetermined control voltage and the n-bit control code and then outputs a third frequency corresponding to an average of the first frequency and a second frequency in response to the predetermined control voltage, the n-bit control code, and the control bit, during the coarse tuning; and outputs the output frequency locked to the reference frequency based on the analog control voltage and the third frequency during the fine tuning. The second frequency is adjacent to the first frequency curve and exists on a second frequency curve among the 2ⁿ frequency curves.

The voltage controlled oscillator may include a capacitor bank and a dummy switched capacitor. The capacitor bank includes “n” switched capacitors to the first frequency on the first frequency curve among the 2ⁿ frequency curves in response to the predetermined control voltage and the n-bit control code. The dummy switched capacitor is connected to the capacitor bank to select the third frequency in response to the control bit.

A gate aspect ratio of the dummy switched capacitor may be ½ of a gate aspect ratio of a switched capacitor controlled by a least significant bit (LSB) of the n-bit control code among the “n” switched capacitors.

The voltage controlled oscillator control circuit may include a phase/frequency detector comparing a phase of the reference frequency with a phase of the output frequency and generating a phase control signal corresponding to a phase difference between the reference frequency and the output frequency; an automatic frequency controller outputting the n-bit control code and the control bit based on a difference between the reference frequency and the output frequency; a charge pump generating a charge corresponding to the phase control signal output from the phase/frequency detector; a loop filter connected to the charge pump; and a switch providing the predetermined control voltage to the voltage controlled oscillator during the coarse tuning and outputting the analog control voltage to the voltage controlled oscillator during the fine tuning, in response to a switching control signal.

The automatic frequency controller may change at least one among the n-bit control code and the control bit based on the difference between the reference frequency and the output frequency, without determining whether the difference therebetween is within a frequency resolution during the coarse tuning.

### BRIEF DESCRIPTION OF THE DRAWINGS

Exemplary embodiments of the present invention will be understood in more detail from the following description taken in conjunction with the attached drawings, in which:

FIG. 1 is a basic block diagram of a conventional phase locked loop (PLL) including an automatic frequency controller (AFC) and a voltage controlled oscillator (VCO);

FIG. 2 illustrates a frequency tuning procedure for the VCO using, conventional binary search;

FIG. 3 is a graph showing the change in a control voltage range of the VCO with respect to a frequency resolution during automatic frequency control;

FIG. 4 is a basic block diagram of a PLL according to an exemplary embodiment of the present invention;

FIG. 5 is a basic block diagram of an AFC illustrated in FIG. 4;

FIG. 6 is a basic block diagram of a VCO illustrated in FIG. 4, which includes an L-C tank circuit with a capacitor bank;

FIG. 7 is a circuit diagram of the L-C tank circuit illustrated in FIG. 6; and

FIG. 8 is a graph showing the change in a control voltage range of the VCO illustrated in FIG. 4 with respect to a frequency resolution during automatic frequency control.

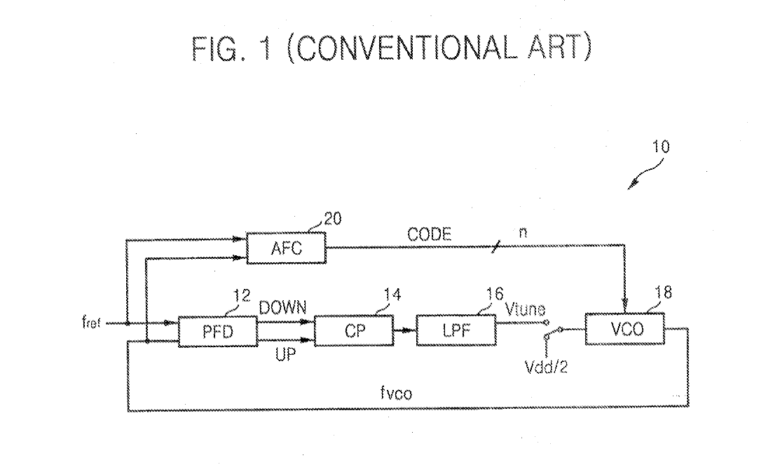

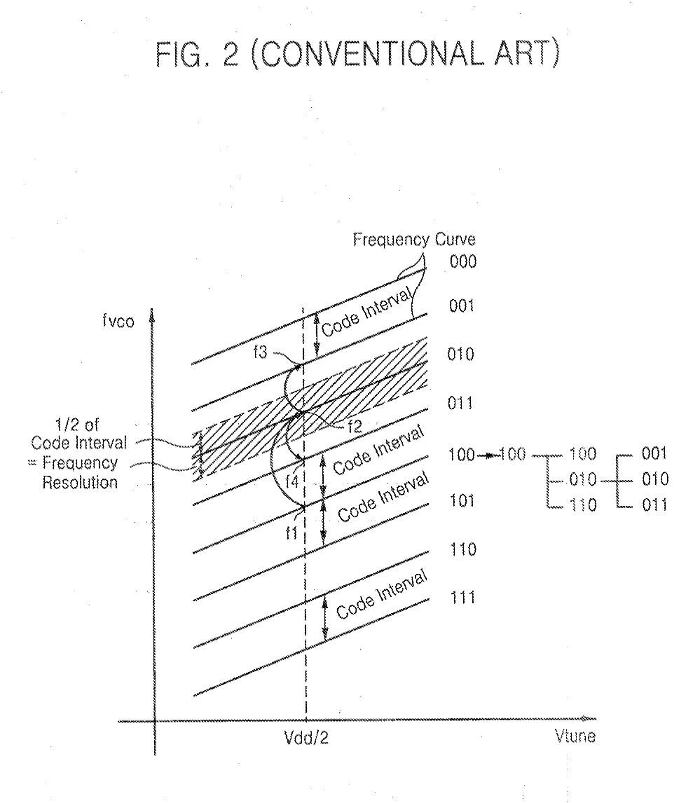

### DETAILED DESCRIPTION OF EXEMPLARY EMBODIMENTS

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

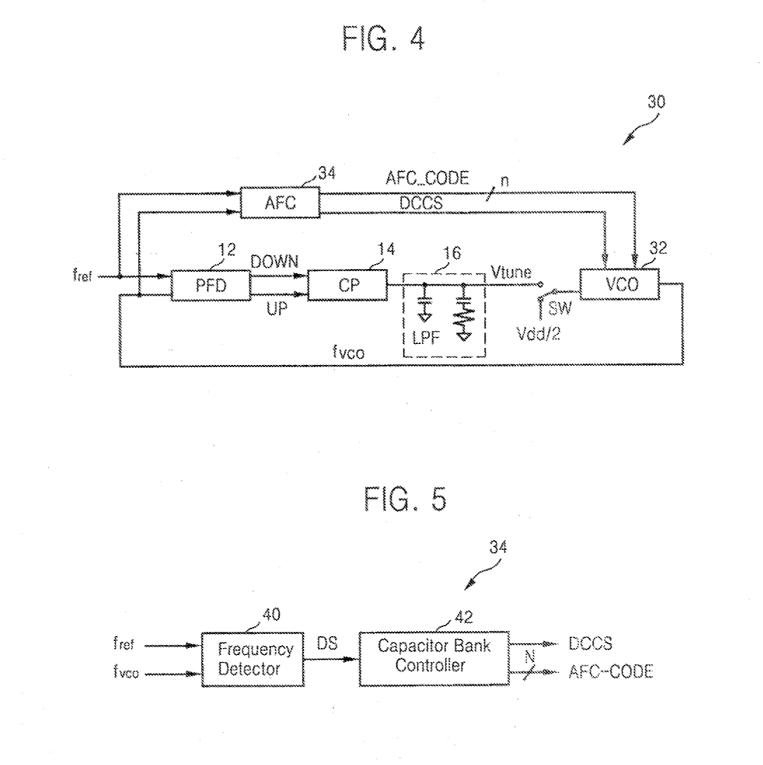

FIG. 4 is a basic block diagram of a phase locked loop (PLL) 30 according to an exemplary embodiment of the present invention. The PLL 30 includes a phase frequency detector (PFD) 12, a charge pump (CP) 14, a low pass filter (LPF) 16, a voltage controlled oscillator (VCO) 32, a switch SW, and an automatic frequency controller (AFC) 34. The PFD 12 receives a reference frequency fref and a feedback frequency fvco and outputs a first phase control signal UP or a second phase control signal DOWN corresponding to a phase difference between the two frequencies fref and the fvco.

When the CP 14 supplies predetermined charges to a capacitor of the LPF 16 in response to the first phase control signal UP, an analog control voltage Vtune of the LPF 16 is increased. Accordingly, the feedback frequency fvco generated by the VCO 32 during fine tuning is increased. When the CP 14 discharges the charge stored on the capacitor of the LPF 16 in response to the second phase control signal DOWN, however, the analog control voltage Vtune of the LPF 16 is decreased. Accordingly, the feedback frequency fvco generated by the VCO 32 during fine tuning is decreased.

The AFC 34 receives the reference frequency fref and the feedback frequency fvco, compares them with each other, and outputs an n-bit control code AFC_CODE (where “n” is a natural number) and a control bit DCCS to the VCO 32 based on a comparison result. For clarity of this description, n=3 is assumed. The control bit DCCS may be one bit but is not limited in the number of bits. The AFC 34 operates only during coarse tuning.

The AFC 34 determines only whether the reference frequency fref is higher or lower than the feedback frequency fvco and does not determine whether a difference between the two frequencies fref and the fvco is within ½ of a code interval. Accordingly, the operating time of the AFC 34 according to an exemplary embodiment of the present invention is remarkably reduced, as compared to the operating time of the conventional AFC 20.

During coarse tuning, the VCO 32 outputs as the feedback frequency fvco a first frequency selected from 2ⁿ discrete frequencies included within a maximum frequency tuning range of the VCO 32 in response to the n-bit control code AFC_CODE. The n-bit control code AFC_CODE may have a value changing from a most significant bit (MSB) to a least significant bit (LSB) but is not restricted thereto. In addition, the n-bit control code AFC_CODE may be changed based on a binary search. The 2ⁿ discrete frequencies exist on 2ⁿ frequency curves, respectively, of the VCO 32.

The VCO 32 outputs as the feedback frequency fvco one frequency between a second frequency higher than the first frequency by ½ of the code interval and a third frequency lower than the first frequency by ½ of the code interval in response to the LSB of the n-bit control code AFC_CODE and the control bit DCCS. Accordingly, during the coarse tuning, the VCO 32 outputs as the feedback frequency fvco a frequency exactly corresponding to ½ of the code interval, regardless of the change in frequency or in manufacturing processes.

The PFD 12, the CP 14, the LPF 16, the VCO 32, the switch SW, and the AFC 34 together form a VCO control circuit. The VCO control circuit generates the n-bit control code AFC_CODE and the control bit DCCS for the coarse tuning and outputs the analog control voltage Vtune for fine tuning of the VCO 32, based on the reference frequency fref and the feedback frequency fvco output from the VCO 32.

FIG. 5 is a basic block diagram of the AFC 34 illustrated in FIG. 4. The AFC 34 includes a frequency detector 40 and a capacitor bank controller 42.

The frequency detector 40 receives the reference frequency fref and the feedback frequency fvco, compares the two frequencies fref and the fvco with each other, and outputs a detection signal DS corresponding to a comparison result. For example, the frequency detector 40 outputs an enabled detection signal, for example, a high level or “1”, when the reference frequency fref is higher than the feedback frequency fvco and outputs a disabled detection signal, for example, a low level or “0”, when the reference frequency fref is lower than the feedback frequency fvco. The capacitor bank controller 42 outputs the n-bit control code AFC_CODE and the control bit DCCS to the VCO 32 in response to the detection signal DS from the frequency detector 40.

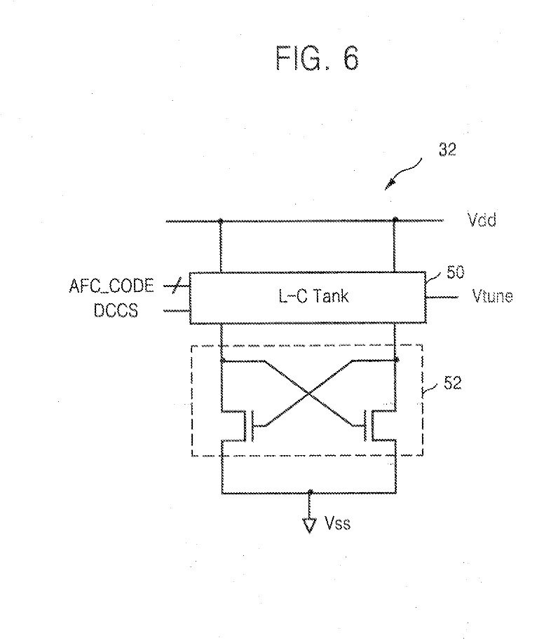

FIG. 6 is a basic block diagram of the VCO 32 illustrated in FIG. 4, which includes an L-C tank circuit 50 with a capacitor bank. Referring to FIG. 6, the VCO 32 includes the L-C tank circuit 50 and a negative conductance generator 52.

During coarse tuning, the L-C tank circuit 50 has discretely variable capacitance responding to the n-bit control code AFC_CODE and the control bit DCCS output from the AFC 34. During fine tuning, the L-C tank circuit 50 has continuously variable capacitance responding to the analog control voltage Vtune output from the LPF 16.

The negative conductance generator 52 provides energy so that the VCO 32 can maintain stable oscillation and may be implemented by cross-coupled transistors. Each of the transistors may have negative resistance or negative conductance to provide the stable oscillation.

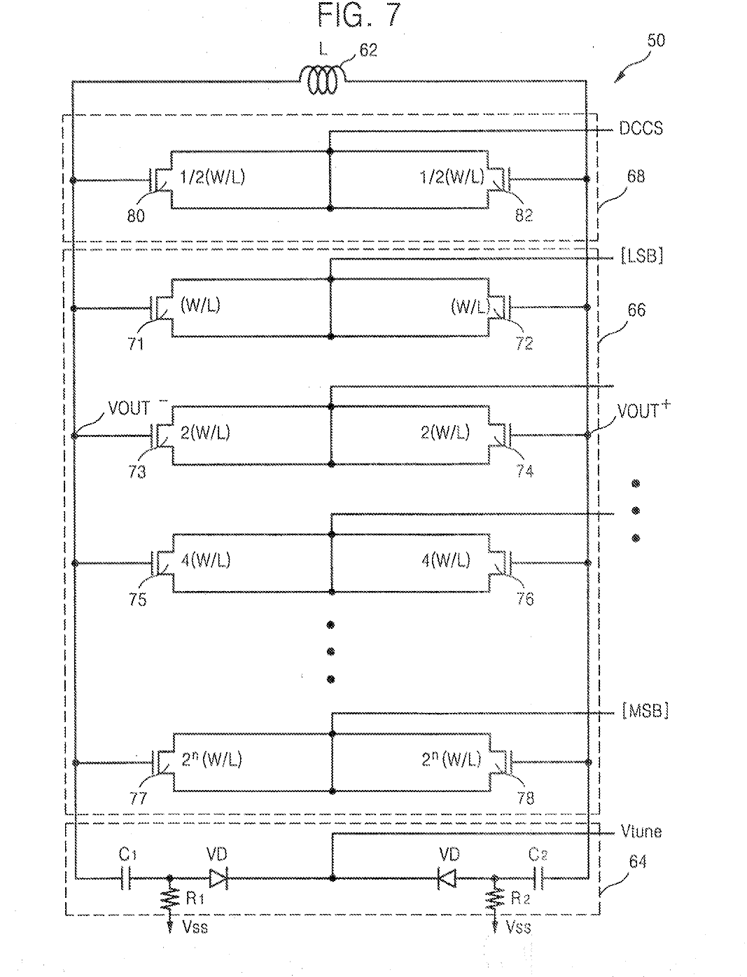

FIG. 7 is a circuit diagram of the L-C tank circuit 50 illustrated in FIG. 6. Referring to FIGS. 6 and 7, the L-C tank circuit 50 includes an inductor block, a variable capacitor block 64, a capacitor bank 66, and a dummy capacitor block 68. The inductor block includes at least one inductive element, for example, an inductor 62 but could also include additional inductors.

The variable capacitor block 64 includes a plurality of capacitors C1 and C2, a plurality of varactor diodes VD, and a plurality of resistors R1 and R2. The capacitance of the variable capacitor block 64 may be controlled in response to the analog control voltage Vtune output from the LPF 16. Accordingly, the analog control voltage Vtune is continuously varied for the fine tuning of the feedback frequency fvco of a feedback signal VOUT output from the VCO 32. The VCO 32 can generate differential feedback signals VOUT⁺ and VOUT⁻.

The capacitor bank 66 includes a plurality of capacitors 71 through 78 controlled by the n-bit control code AFC_CODE. For example, the capacitor bank 66 may include binary-weighted switched capacitors 71 through 78 for the coarse tuning of the feedback frequency fvco of the feedback signal VOUT⁺ output from the VCO 32.

When a ratio of a channel width to a channel length, W/L (referred to as a gate aspect ratio) is 1 in each of the capacitors 71 and 72 controlled by the LSB of the n-bit control code AFC_CODE, where each of the capacitors is specifically a “capacitor formed using a transistor” but the term “capacitor” is used for convenience of the description, each of the capacitors 73 and 74 controlled by the first bit [xxx1x] from the LSB of the n-bit control code AFC_CODE has a gate aspect ratio of 2. Each of the capacitors 75 and 76 controlled by the second bit [xx1xx] from the LSB of the n-bit control code AFC_CODE has a gate aspect ratio of 4. Each of the capacitors 77 and 78 controlled by the MSB of the n-bit control code AFC_CODE has a gate aspect ratio of 2ⁿ, where “n” is a natural number and indicates a total bit number of the n-bit control code AFC_CODE.

The dummy capacitor block 68 includes one or more dummy capacitors 80 and 82. The capacitance of the dummy capacitor block 68 is discretely controlled in response to the control bit DCCS. For example, when each of the capacitors 71 and 72 controlled by the LSB of the n-bit control code AFC_CODE has a gate aspect ratio of 1, each of the dummy capacitors 80 and 82 may have a gate aspect ratio of ½. In other words, the VCO 32 includes the dummy capacitors 80 and 82 in order to obtain a frequency corresponding to ½ of a code interval. Accordingly, during coarse tuning, the L-C tank circuit 50 outputs a feedback frequency corresponding to ½ of a code interval in response to the LSB of the n-bit control code AFC_CODE and the control bit DCCS.

The frequency tuning operation of the PLL 30 according to an exemplary embodiment of the present invention will be described in detail with reference to FIGS. 4 through 8 below.

During coarse tuning, the switch SW provides an initial control voltage to the VCO 32 in response to a control signal (not shown) that controls the switch SW. The capacitor bank controller 42 included in the AFC 34 provides “100” as the initial control code AFC_CODE fed to the VCO 32. The initial control voltage may be ½ of the power supply voltage Vdd but is not restricted thereto. The VCO 32 outputs as the feedback frequency fvco a frequency, referred to as a “code 100 frequency f11” or a “frequency on a frequency curve corresponding to the code of 100”, corresponding to the initial control voltage Vdd/2 and the control code AFC_CODE of “100”.

The frequency detector 40 included in the AFC 34 compares the reference frequency fref with the code 100 frequency f11 and outputs a detection signal DS corresponding to a comparison result. For example, when the reference frequency fref is higher than the code 100 frequency f11, the frequency detector 40 outputs an enabled detection signal DS. When the reference frequency fref is lower than the code 100 frequency f11, the frequency detector 40 outputs a disabled detection signal DS. The frequency detector 40 does not determine whether a difference between the reference frequency fref and the feedback frequency fvco is within ½ of a code interval but outputs the detection signal DS considering only the difference therebetween.

The capacitor bank controller 42 may output “010” as the control code AFC_CODE in response to the enabled detection signal DS or may output “110” as the control code AFC_CODE in response to the disabled detection signal DS. The FCO 32 outputs as the feedback frequency fvco a frequency, referred to as a “code 010 frequency f12”, corresponding to the initial control voltage Vdd/2 and the control code AFC_CODE of “010”.

The frequency detector 40 included in the AFC 34 compares the reference frequency fref with the code 010 frequency f12 and outputs a detection signal DS corresponding to a comparison result. For example, when the reference frequency fref is higher than the code 010 frequency f12, the frequency detector 40 outputs the enabled detection signal DS. When the reference frequency fref is lower than the code 010 frequency f12, the frequency detector 40 outputs the disabled detection signal DS. The capacitor bank controller 42 may output “001”as the control code AFC_CODE in response to the enabled detection signal DS or may output “011” as the control code AFC_CODE in response to the disabled detection signal DS.

When the capacitor bank controller 42 outputs “011” as the control code AFC_CODE, the VCO 32 outputs as the feedback frequency fvco a frequency, referred to as a “code 011 frequency”, corresponding to the control code AFC_CODE of “011”.

The frequency detector 40 included in the AFC 34 compares the reference frequency fref with the code 011 frequency and outputs a detection signal DS corresponding to a comparison result. For example, when the reference frequency fref is higher than the code 011 frequency, the frequency detector 40 outputs the enabled detection signal DS. When the reference frequency fref is lower than the code 011 frequency, the frequency detector 40 outputs the disabled detection signal DS.

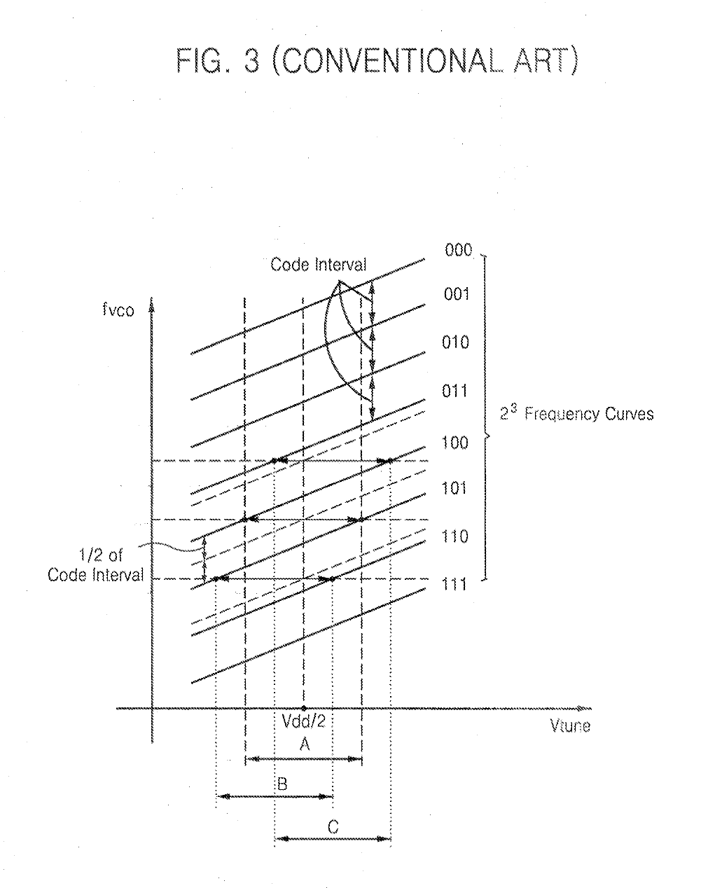

The capacitor bank controller 42 outputs “010” as the control code AFC_CODE and simultaneously outputs “1” as the control bit DCCS, in response to the enabled detection signal DS. Accordingly, the capacitance of the dummy capacitor block 68 included in the VCO 32 is varied in response to the control bit DCCS of “1”. In addition, the dummy capacitor block 68 forms a new frequency curve in the middle between a frequency curve corresponding to the control code AFC_CODE of “010” and a frequency curve corresponding to the control code AFC_CODE of “011”. A frequency on the frequency curve formed by the dummy capacitor block 68 exactly corresponds to ½ of the code interval, as shown in FIG. 3.

The VCO 32 outputs as the feedback frequency fvco a frequency corresponding to the initial control voltage Vdd/2, the control code AFC_CODE of “010”, and the control bit DCCS of “1”.

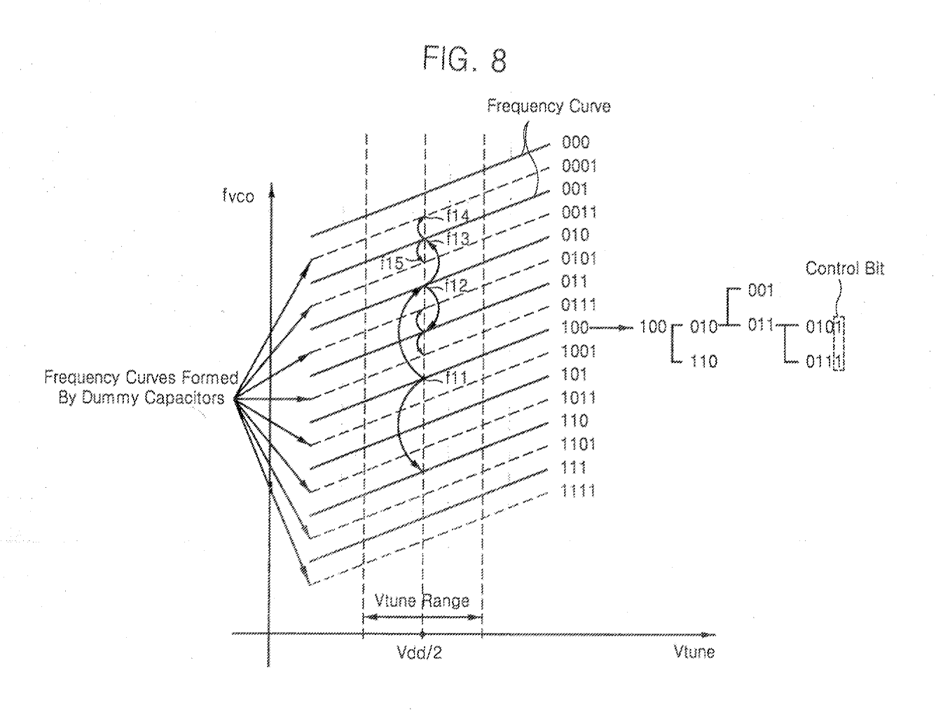

As shown in FIG. 8, when capacitor bank controller 42 outputs “011” as the control code AFC_CODE and simultaneously outputs “1” as the control bit DCCS, in response to the disabled detection signal DS, the dummy capacitor block 68 forms a new frequency curve in the middle between a frequency curve corresponding to the control code AFC_CODE of “011” and a frequency curve corresponding to the control code AFC_CODE of “100”. A frequency on the frequency curve formed by the dummy capacitor block 68 exactly corresponds to ½ of the code interval.

The VCO 32 outputs as the feedback frequency fvco a frequency corresponding to the initial control voltage Vdd/2, the control code AFC_CODE of “011”, and the control bit DCCS of “1”.

In addition, the VCO 32 outputs as the feedback frequency fvco a frequency f14 or f15 on a frequency curve newly formed based on the LSB of the n-bit control code AFC_CODE and the control bit DCCS of “1”, using the above-described method.

During fine tuning, the switch SW provides an output voltage of the LPF 16, that is, the analog control voltage Vtune to the VCO 32 in response to a control signal (not shown). The VCO 32 outputs as the feedback frequency fvco a predetermined frequency on a frequency curve corresponding to “0101” or a predetermined frequency on a frequency curve corresponding to “0111” based on the analog control voltage Vtune varying with a phase difference between the reference frequency fref and the feedback frequency fvco. The frequency curve corresponding to “0101” or “0111” has been newly formed based on the LSB of the n-bit control code AFC_CODE and the control bit DCCS of “1” during coarse tuning.

During coarse tuning, a conventional VCO outputs as a feedback frequency a frequency on a frequency curve selected by a control code. A VCO according to an exemplary embodiment of the present invention, however, outputs a frequency corresponding to ½ of a code interval as the feedback frequency.

As described above, a PLL using VCO and a frequency tuning method for the VCO according to an exemplary embodiment of the present invention can obtain an exact control voltage range of the VCO regardless of the change in frequency or in manufacturing processes, can reduce the coarse tuning time, can detect a frequency exactly corresponding to ½ of a code interval, and can output the detected frequency as a feedback frequency.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A coarse tuning method for a voltage controlled oscillator, comprising:
outputting a first frequency on a first frequency curve selected from 2ⁿ frequency curves of the voltage controlled oscillator based on a predetermined control voltage and an n-bit control code; and
outputting a third frequency corresponding to an average of the first frequency and a second frequency in response to the predetermined control voltage, the n-bit control code, and a control bit,
wherein the second frequency is adjacent the first frequency curve and exists on a second frequency curve among the 2ⁿ frequency curves.

2. A frequency tuning method for a voltage controlled oscillator included in a phase locked loop, the frequency tuning method comprising:
providing a predetermined control voltage to the voltage controlled oscillator during coarse tuning;
outputting a first frequency selected from 2ⁿ discrete frequencies included in a frequency tuning range of the voltage controlled oscillator based on the predetermined control voltage and an n-bit control code;
outputting a third frequency corresponding to an average of the first frequency and a second frequency in response to the predetermined control voltage, the n-bit control code, and a control bit; and
locking an output frequency of the voltage controlled oscillator to a reference frequency based on an analog control voltage and the third frequency during fine tuning,
wherein the second frequency is adjacent the first frequency among the 2ⁿ discrete frequencies and the third frequency is used as an initial frequency during the fine tuning.

3. The tuning method of claim 1, wherein the outputting of the third frequency comprises outputting the third frequency in response to the predetermined control voltage, a least significant bit (LSB) of the n-bit control code, and the control bit.

4. The tuning method of claim 2, wherein the outputting of the third frequency comprises outputting the third frequency in response to the predetermined control voltage, a least significant bit (LSB) of the n-bit control code, and the control bit.

5. The frequency tuning method of claim 2, further comprising generating at least one control code among the n-bit control code and the control bit based only a difference between the reference frequency and the output frequency without determining whether the difference therebetween is within a frequency resolution during the coarse tuning.

6. A phase locked loop comprising:
a voltage controlled oscillator; and
a voltage controlled oscillator control circuit generating an n-bit control code and a control bit for coarse tuning of the voltage controlled oscillator and outputting an analog control voltage for fine tuning of the voltage controlled oscillator, based on a reference frequency and an output frequency of the voltage controlled oscillator,
wherein the voltage controlled oscillator outputs a first frequency on a first frequency curve finally selected from 2ⁿ frequency curves of the voltage controlled oscillator based on a predetermined control voltage and the n-bit control code and then outputs a third frequency corresponding to an average of the first frequency and a second frequency in response to the predetermined control voltage, the n-bit control code, and the control bit, during the coarse tuning; and outputs the output frequency locked to the reference frequency based on the analog control voltage and the third frequency during the fine tuning, and
the second frequency is adjacent the first frequency curve and exists on a second frequency curve among the 2ⁿ frequency curves.

7. The phase locked loop of claim 6, wherein the voltage controlled oscillator comprises:
a capacitor bank including n switched capacitors to select the first frequency on the first frequency curve among the 2ⁿ frequency curves in response to the predetermined control voltage and the n-bit control code; and
a dummy switched capacitor connected to the capacitor bank to select the third frequency in response to the control bit.

8. The phase locked loop of claim 7, wherein a gate aspect ratio of the dummy switched capacitor is ½ of a gate aspect ratio of a switched capacitor controlled by a least significant bit (LSB) of the n-bit control code among the n switched capacitors.

9. The phase locked loop of claim 6, wherein the voltage controlled oscillator control circuit comprises:
a phase/frequency detector comparing a phase of the reference frequency with a phase of the output frequency and generating a phase control signal corresponding to a phase difference between the reference frequency and the output frequency;
an automatic frequency controller outputting the n-bit control code and the control bit based on a difference between the reference frequency and the output frequency;
a charge pump generating a charge corresponding to the phase control signal output from the phase/frequency detector;
a loop filter connected to the charge pump; and
a switch providing the predetermined control voltage to the voltage controlled oscillator during the coarse tuning and outputting the analog control voltage to the voltage controlled oscillator during the fine tuning, in response to a switching control signal.

10. The phase locked loop of claim 9, wherein the automatic frequency controller changes at least one among the n-bit control code and the control bit based on the difference between the reference frequency and the output frequency without determining whether the difference therebetween is within a frequency resolution during the coarse tuning.
